(19) United States
(12) Patent Application Publication
(10) Pub. No.: US 2007/0205096 A1
(43) Pub. Date: Sep. 6, 2007

(54) Magnetron based wafer processing

(76) Inventor: Makoto Nagashima, Tokyo (JP)

Correspondence Address: TRAN & ASSOCIATES, 6768 MEADOW VISTA CT., SAN JOSE, CA, 95135, US

(21) Appl. No.: 11/369,164

(22) Filed: Mar. 6, 2006

(51) Int. Cl. C23C 14/00

(52) U.S. Cl. 204/192.12; 204/298.16

(57) ABSTRACT

A wafer magnetron includes a support for supporting a wafer; a generator to provide an electric field substantially perpendicular to the wafer surface; and a magnet system for generating a magnetic field, a portion of the magnetic field lines being parallel to the wafer surface.

### BACKGROUND

The present invention relates to an apparatus used for processing a semiconductor substrate.

FTS (Facing Target Sputtering) method is a semiconductor fabrication technique that provides high density plasma, high deposition rate at low working gas pressure to form high quality thin film. In a facing target type of sputtering apparatus, at least a pair of target planes are arranged to face each other in a vacuum vessel, and magnetic fields are generated perpendicularly to the target planes for confining plasma in the space between the facing target planes. The substrate is arranged so as to be positioned at the side of the space so that films are produced on the substrate by sputtering.

As discussed in U.S. Pat. No. 6,156,172, a typical FTS apparatus includes a vacuum vessel for defining therein a confined vacuum chamber, an air exhausting unit having a vacuum pump system to cause a vacuum via an outlet, and a gas supplying unit for introducing sputtering gas into the vacuum vessel. A pair of target portions are arranged in the vacuum vessel in such a manner that a pair of rectangular shape cathode targets face each other so as to define a predetermined space therebetween.

Another FTS apparatus discussed in the '172 patent confines sputtering plasma in a box type of plasma space using a pair permanent magnets so as to face N and S-pole generate magnetic flux circulating perpendicularly the outside space of the first facing targets which defines facing target mode in combination with electric fields perpendicular to target planes in plasma space. The pair of magnets generate a conventional magnetron mode with a closed magnetic flux from the pole of magnets in the vicinity of the outside area of the pair of target planes in addition to the facing target mode. The cathodes of all the targets are arranged so as to recoil and confine the electrons into the plasma space by the aid of both the facing target mode and the magnetron mode.

To improve the deposition speed of the equipment, the '172 patent discloses an FTS apparatus which includes: an arrangement for defining box-type plasma units supplied therein with sputtering gas mounted on outside wall-plates of a closed vacuum vessel; at least a pair of targets arranged to be spaced apart from and face one another within the box-type plasma unit, with each of the targets having a sputtering surface thereof; a framework for holding five planes of the targets or a pair of facing targets and three plate-like members providing the box-type plasma unit so as to define a predetermined space apart from the pair of facing targets and the plate-like members, which framework is capable of being removably mounted on the outside walls of the vacuum vessel with vacuum seals; a holder for the target having conduits for a coolant; an electric power source for the targets to cause sputtering from the surfaces of the targets; permanent magnets arranged around each of the pair of targets for generating at least a perpendicular magnetic field extending in a direction perpendicular to the sputtering surfaces of the facing targets; devices for containing the permanent magnets with target holders, removably mounted on the framework; and a substrate holder at a position adjacent the outlet space of the sputtering plasma unit in the vacuum vessel.

In sputtering, ionized atoms bombards a surface. The most common form of sputtering process is sputter deposition where the ionized atoms by bombarding a target, eject neutral atoms from the target material to deposit on a substrate placed in a suitable location to intercept the ejected atoms. The other form of sputtering process is sputter etch where the ionized atoms bombard a substrate to form a pattern on the substrate.

The ionized atoms are typically large atomic weight gases, such as argon and xenon, created in a plasma and then accelerated into the target cathode by an electric field. In some cases, reactive gases instead of inert gas of argon or xenon are used, resulting in the deposition of a compound of the target material and the reactive gas species. A dc diode sputtering system uses a high dc voltage, typically between 200 to 800 V, to create a plasma discharge, comprising a target material as a cathode electrode, and a substrate as an anode electrode where deposition occurs. The dc diode sputtering systems are characterized by high voltages and low currents, and thus susceptible to charging and arcing. Further, dc diodes are inadequate for dielectric deposition due to the rapid build-up of positive charges on the surface of the insulator and the difficult of secondary electron emission from the cathode.

Replacing the dc power supply with an rf (radio frequency) power supply, typically at a frequency of 13.56 MHz, results in an rf sputtering system with reduced charging and arcing problems. The rf voltage also results in changes to the electron and ion motions, producing better energy coupling and higher plasma densities.

Further improvement to the sputtering system to improve the deposition rate is the introduction of a magnetron system, consisting of an external magnetic field superimposed upon the electric field. Magnetron sputter devices are characterized by crossed electric and magnetic fields, with the electric field perpendicular and the magnetic field parallel to the target cathode. The magnetic field confines the glow discharge plasma, and traps the electrons moving under the influence of the electric field, resulting in an increase in the gas atom-electron collision probability, the ionization rate of argon atoms, the frequency of argon ions striking the target, and thus leading to a higher sputter deposition rate. The basic arrangement of the magnetic field is to create a closed loop travel of the electrons which establishes the region of preferred sputtering.

Generally, a permanent magnet structure is employed to generate the magnetic field, but electromagnetic devices can also be used for this purpose. The magnetic field can also be moved by a motor drive to average out the intrinsic nonuniformity, and to spread the erosion pattern on the target face. The ion bombardment of the target also impart a significant amount of thermal energy to the target, thus the heat generated during sputtering must be adequately removed to ensure optimum performance of a magnetron system. By applying a back bias to the substrate, the deposited film can have certain amount of control of ion bombardment of the growth films. This is called bias sputtering, resulting in densifying and planarizing the depositing film.

Another improvement to sputter technology is to ionize the sputtered atoms to enhance the directionality of a deposition, a technique sometimes called IPVD (ionized physical vapor deposition). An IPVD system is based on a magnetron sputtering, with the addition of an inductively coupled rf plasma located between the cathode and the substrate for in-flight ionization of the sputtered atoms. Thus there are two somewhat separate plasmas within the process chamber with the same background gas. One is a conventional dc or rf plasma of the magnetron, located close to the cathode target, so that ions can strike the cathode target to cause sputter emission of the target atoms. A second plasma, generated by the inductive coil, is presented between the target cathode and the substrate. Thus a high fraction of the sputtered atoms emitted from the target are ionized by electron bombardment when they pass through this plasma. The ionized sputtered atoms drift within the plasma, and can either accelerated to the substrate due to the plasma potential (typically +10 V) and the substrate potential (0 to −50 V), or accelerated toward the target cathode by the magnetron voltage (typically −400 V), sputtering more atoms from the cathode.

### SUMMARY

In a first aspect, a wafer magnetron includes a support for supporting a wafer; a generator to provide an electric field substantially perpendicular to the wafer surface; and a magnet system for generating a magnetic field, a portion of the magnetic field lines being parallel to the wafer surface.

In a second aspect, a wafer magnetron processing chamber includes a vacuum process chamber; a plasma generator to generate a plasma within the process chamber; a support for supporting a wafer, the wafer positioned within the process chamber; a generator to provide an electric field substantially perpendicular to the wafer surface; and a magnet to generate a magnetic field having a portion of the magnetic field lines parallel to the wafer surface.

In a third aspect, a method for processing a semiconductor wafer includes trapping electrons in the vicinity region of the wafer surface by a wafer magnetron effect, wherein the trapped electrons ionize the atoms and ions before reaching the wafer surface; and increasing an ionization rate for atoms and ions bombarding the wafer surface.

The system ionizes the neutral atoms by employing a magnetron effect at the wafer substrate rather than just at the target. By establishing a magnetic field in the vicinity of the substrate to trap electrons, the neutral atoms traveling to the substrate can be ionized by collisions with the electron cloud. The electrons in this magnetic confinement can have sufficient energy to ionize incoming atoms and not being annihilated by the ions. A high proportion of the incoming atoms can be excited by this electron cloud and then accelerated by a back bias field onto the wafer surface. The high number of mobile ions at the surface can provide enough surface mobility to significantly decrease the required deposition temperature, possibly even down to room temperature.

The electron cloud can be self-generated by secondary electron emission, or by electron capturing from nearby plasma environment. The electrons can be ejected from the substrate by the energetic bombardment of the incoming atoms or ions, and they become captured in the electron cloud above the wafer by the present invention wafer-vicinity magnetron. The electron cloud can also be generated from ionizing radiation, microwaves or electron bombardment, with electron bombardment is preferable because it can be contained in the specific area of interest. The electron population can be generated or maintained by a field emission tip array or an electron gun at the wafer-vicinity magnetron boundary. By adjusting the electron flow and geometry, the ions can even be partially neutralized before hitting the wafer surface, giving some additional control. By shaping the magnetic field dynamically, the imperfections caused by the non-uniform deposition pattern of standard magnetrons can further be corrected.

### BRIEF DESCRIPTION OF THE DRAWINGS

FIG. 1 shows a typical prior art magnetron sputter system with an ionized plasma assembly.

FIG. 2 shows an embodiment of the present invention wafer-vicinity magnetron assembly.

FIG. 3 shows an embodiment of the present invention wafer-vicinity magnetron assembly in a planar magnetron sputtering system.

FIG. 4 shows an embodiment of the present invention wafer-vicinity magnetron assembly in a hollow cathode magnetron sputtering system.

FIG. 5 shows one embodiment of a face target sputtering (FTS) system.

### DESCRIPTION

In one embodiment, a system generates a wafer-vicinity magnetron effect, providing a cross electric field and a magnetic field in the vicinity of the wafer. The presence of the wafer-vicinity magnetron creates a magnetic confinement of the electrons in the region near the wafer surface, thus trapping an electron cloud and providing a means for ionizing the atoms to strike the wafer.

The wafer-vicinity magnetron is independent of the conventional magnetron technology, thus it can be used in a magnetron sputtering system where there would be two magnetron units, one for the cathode target and one for the wafer substrate. The present invention wafer-vicinity magnetron can also be used in systems not employing conventional magnetron technology, such as non-magnetron dc or rf diode sputter systems, plasma-enhanced chemical vapor deposition systems, reactive ion etching systems, ion beam system, or even thermal deposition or processing system.

The wafer-vicinity magnetron provides a magnetic field and an electric field in the vicinity of the wafer substrate and the presence of electrons to be trapped in the electromagnetic field. The magnetic field can be generated from a permanent magnet system or from an electromagnetic device. The electric field can be generated from a wafer back bias system, or by an externally applied electric field. The electrons can be externally supplied or internally present in the process chamber, for example due to a plasma condition or due to the bombardment of the substrate to liberate secondary electrons.

The wafer-vicinity magnetron can be directed toward the sputter deposition, to provide ionized sputtered atoms having high energy to reach the wafer substrate. One preferred embodiment of the present invention wafer-vicinity magnetron is to provide low temperature deposition by sputtered ions having enough energy to provide the surface mobility needed for either a surface reaction or a crystalline arrangement.

The wafer-vicinity magnetron effect could enable crystalline deposition virtually independent of wafer temperature, and possibly even at room temperature. Currently, most prior art systems use temperature to provide enough surface mobility or with a back bias potential where the ions can be accelerated into the wafer, lowering the required surface temperature. However, the back bias potential technique is not really effective since most of the atoms reaching the wafer are neutral, and thus not affected by the back bias field. The present invention wafer-vicinity magnetron provides a method to ionize the atoms in the vicinity of the wafer, and together with a back bias field, accelerating the ions into the wafer to provide surface mobility and thus reducing wafer temperature. The atom ionization is accomplished by a wafer-vicinity magnetron trap with various ways to generate the trapped electrons.

Various techniques can be used to ionize atoms within a given volume. Ionizing radiation, microwaves or electron bombardment can all be used to create a plasma. Of these methods, electron bombardment is preferable because it can be contained in the specific area of interest. The electrons are ejected from the substrate by the energetic depositions and they end up in the electron cloud above the wafer. The electrons in this cloud have sufficient energy to ionize incoming atoms and not being annihilated by the ions. A magnetic field is used to contain the electron charge. The electrons are then used to ionize and excite a very high proportion of the incoming ions, which are then accelerated by the back bias field onto the wafer surface. The high number of mobile ions at the surface can significantly decrease the required deposition temperature, down to room temperature.

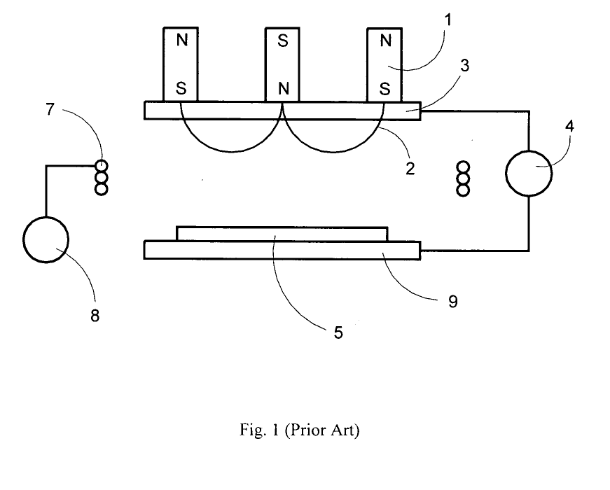

FIG. 1 shows a prior art sputter system, comprising a permanent magnet unit 1, creating a magnetic field 2 in the vicinity of the target cathode 3. A power supply 4 is applied to the target cathode electrode 3 and a substrate anode electrode 9, supporting a wafer 5. The power supply 4, either dc or rf, ionizes a background gas, such as an inert gas of argon or xenon, or a reactive gas of oxygen or nitrogen to create a plasma between the two electrodes. The power supply 4 also generates an electric field, pulling electrons toward the substrate anode 5 and the positive argon ions toward the target cathode 3. When the argon ions strike the target cathode, target atoms together with secondary electrons are emitted. The magnetic field traps the electrons and confines them to the target surface. This electron cloud further ionizes the argon atoms to increase the strike frequency to the target surface. The argon ions strike the target according to a distribution around the centerline of the ion path to generate a characteristic gaussian erosion pattern. FIG. 1 further includes an ionized plasma setup, comprising an inductive coil 7 connected to a power generator 8. The inductive coil 7 generates a second plasma between the target 3 and the substrate 9, to ionize the sputtered atoms from the target.

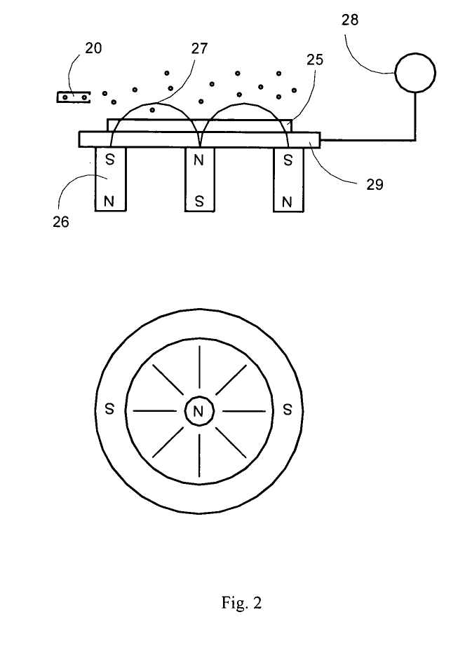

FIG. 2 shows an embodiment of a wafer-vicinity magnetron assembly, comprising a magnet system 26 to generate a magnetic field 27 in the vicinity of a wafer 25, located on a support 29. The wafer-vicinity magnetron assembly also includes a power supply 28 connected to the support 29 to provide an electric field in the vicinity of the wafer. The magnet system 26 can include permanent magnets or electromagnetic devices. The magnet system 26 is shown to be under the wafer 25, but can be essentially almost anywhere, for example on top or on the side of the wafer. The wafer-vicinity is defined to be closer to the wafer than to a target, in relation to a target-vicinity magnetron system. The wafer 25 is shown on a solid support 29, but any wafer support can be used, such as a 3-pin support or simply a chamber wall section. The electric field is shown to be generated by a power supply such as a back bias supply 28 connected to the wafer support 29, but any means to generate an electric field can be used, such as a power supply to generate a plasma, or simply an external electric field outside the assembly. Also shown in FIG. 2 is a top view of the magnet unit, comprising two magnets arranging to have magnetic field lines radiated from the center to the edge. The system further includes an optional electron gun 20 to provide electrons as needed.

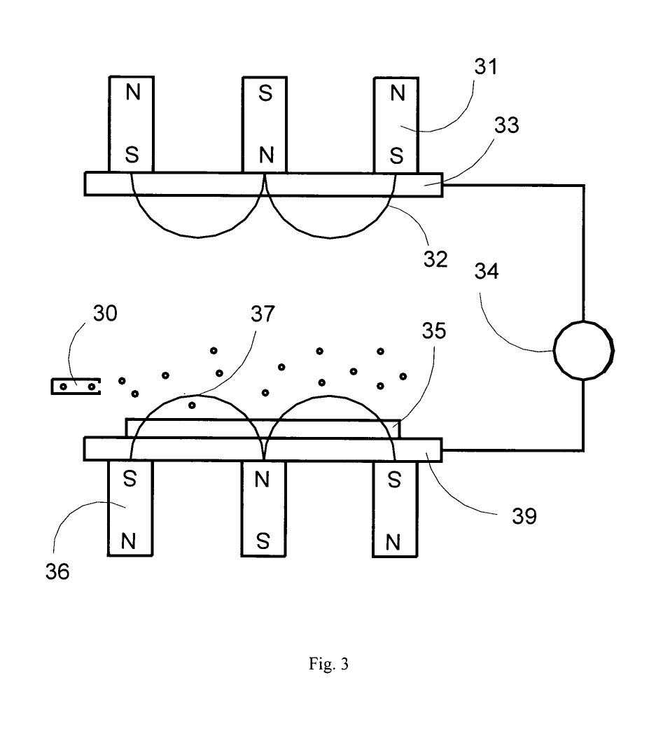

FIG. 3 shows an embodiment of a wafer-vicinity magnetron assembly in a magnetron sputter system. The system includes a magnet unit 31, creating a magnetic field 32 in the vicinity of the target cathode 33. A power supply 34 is applied to the target cathode electrode 33 and a substrate anode electrode 39, supporting a wafer 35. The power supply 34, either dc or rf, ionizes a background gas, such as an inert gas of argon or xenon, or a reactive gas of oxygen or nitrogen to create a plasma between the two electrodes. The power supply 34 also generates an electric field, pulling electrons toward the substrate anode 35 and the positive argon ions toward the target cathode 33. The magnetic field 32 traps the electrons in the vicinity of the target 33, enhancing the sputtering rate of the magnetron sputter system. A wafer-vicinity magnetron assembly is included, comprising a magnet system 36 to generate a magnetic field 37 in the vicinity of a wafer 35. When the target atoms leave the sputtering target 33 to deposit on the wafer 35, the bombardment action emits secondary electrons from the wafer surface. The electrons are trapped in the wafer-vicinity magnetron area, and thus can ionize the target atoms before they hit the wafer surface. The system further includes an optional electron gun 30 to provide electrons as needed.

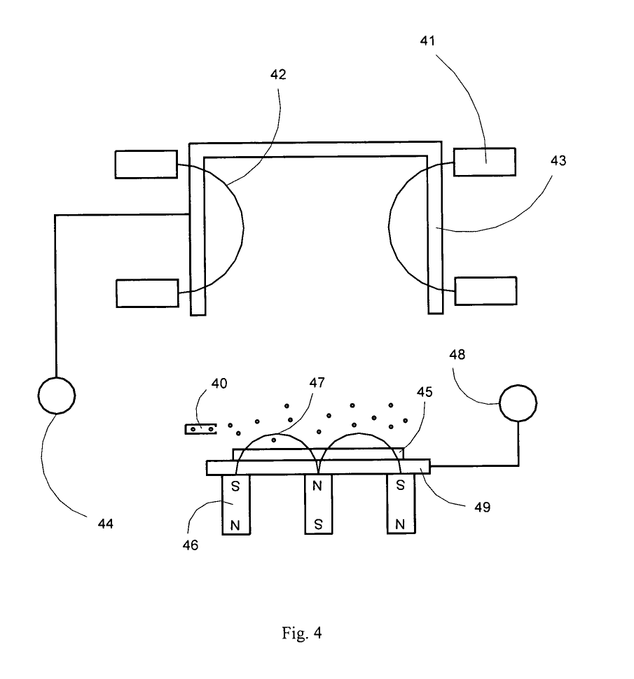

FIG. 4 shows an embodiment of a wafer-vicinity magnetron assembly in a hollow cathode sputter system. The system includes a magnet unit 41, creating a magnetic field 42 in the vicinity of the target cathode 43, arranged to form a hollow cavity. A power supply 44 is applied to the target cathode electrode 43 and an anode electrode (not shown). The power supply 44 creates a plasma in the hollow cavity, bombarding the target cathode 43 with positive ions. The magnetic field 42 traps the electrons in the vicinity of the target 43, enhancing the sputtering rate of the magnetron sputter system. A wafer-vicinity magnetron assembly is included, comprising a magnet system 46 to generate a magnetic field 47 in the vicinity of a wafer 45, located on a support 49. The wafer-vicinity magnetron assembly further includes a back bias power supply 48 to generate an electric field in the vicinity of the wafer surface. The system further includes an optional electron gun 40 to provide electrons as needed.

Though the sputtering assembly shown is either a planar magnetron sputtering assembly or a hollow cathode magnetron sputtering assembly, any sputtering assembly can be used in the present invention, for example, a conical sputtering assembly, a cylindrical magnetron sputtering assembly, a s-gun sputtering assembly, a facing target system sputtering assembly.

The magnetic field generated by the wafer-vicinity magnetron is preferably spread so the magnetic field covers a larger wafer area, thus providing a more uniform deposition. This can be accomplished by spreading the magnetic poles, by superimposing the magnetic fields of several magnets to shape the magnetic field, or by a motor drive system to move the magnet system. If the magnetic field parallel to the wafer surface is increased, the sputter atom ionization rate also increases, but it would be saturated. Thus, there is a limit to the useful intensity of the magnetic field, depending on electric field, particle velocity, chamber pressure, plasma pressure, and other physical parameters of the sputtering system.

The power supply on the target cathode may be a dc voltage or a rf voltage. In dc sputtering, the power supply applied to the target is typically between −200 to −800 V, with the other electrode connected to the wafer substrate or to the chamber ground. The power supply on the wafer back bias may be a dc voltage or an rf voltage, with the power supply applied to the target is typically between 10 to −100 V.

RF frequency is typically a rf frequency of 13.56 MHz for use with a LC matching network, or a rf frequency of 1.9 MHz for use with a variable frequency-matching network. At the rf frequency, the electrons response more readily than the ions due to their higher mobility, and thus this creates a net negative electric field bias on the target or the wafer.

The background gas is typically at a pressure from 0.5 mTorr to about 100 mTorr to provide the initiation and sustaining the plasma. The gas flow is typically about 10-100 sccm.

Electrons emitted due to ion bombardment are accelerated and collide with gas atoms. At low pressures or high energy, electrons travels far and generated ions can be easily lost. Thus, magnetron system can trap the electrons, primary for the target magnetron, and secondary for the wafer magnetron to improve ionization efficiencies. A parallel magnetic field to the cathode or wafer surface can confine electrons to the vicinity of the cathode or wafer and therefore can further ionize the atoms. The ExB electron drift currents makes a closed loop, and thus being trapped near the cathode or wafer surface. The wafer magnetron effect is created by an array of magnets to produce a magnetic field normal to the electric field at the wafer surface.

The ion bombardment to the target cathode also provides significant thermal energy to the target, and thus target magnetron system must include a cooling assembly since magnetron sputtering system produces very large ion currents, causing a very intense and localized heating of the target. In contrast, this ion current heating is a desired feature of the present invention wafer-vicinity magnetron since the high energy of the ions is beneficial to the thin film deposition, to provide the thermal energy needed for either the deposition reaction or the surface mobility needed for low temperature crystalline formation.

The wafer magnetron assembly utilizes magnetic field in proximity to the wafer to produce electron traps near the wafer, thereby increasing the ionization rate of ions and atoms reaching the wafer. The electric field, created by the wafer back bias or wafer to ground configuration, is substantially perpendicular to the wafer surface. The magnetic field from the magnetron usually starts and returns to the wafer surface to form a closed arch. By shaping the magnetic configuration into a circular or racetrack shape, the electrons will follow a closed loop drift path above the surface of the wafer, providing the ionization by colliding with the atoms present near the wafer surface. The required magnetic flux density is generally greater than about 200 gauss. To improve uniformity across the wafer, the drift path is relatively translated across the surface of the wafer. This can be achieved by either moving the wafer or preferably, by moving the magnet by means of a motor drive, the so-called rotating-magnet magnetron system.

A rf back bias can develop large electron currents due to the high electron mobility, and thus if a capacitor is placed in series, it allows a negative bias to accumulate, typically half the peak-to-peak rf voltage. This bias creates an electric field for the wafer substrate, trapping the secondary electron emission from the wafer with the wafer-vicinity magnetron assembly.

Also, by splitting the rf power between the cathode and the substrate, the substrate acts as a cathode and thus is bombarded by ions from the plasma. By applying a wafer magnetron assembly, the electron emission from the ion bombardment can be trapped, to further ionize the incoming atoms or ions.

The electron population can further be maintained by an electron gun such as a hollow cathode electron source, a filament electron beam, or a field emission tip array at the magnetron boundary. By adjusting the electron flow and geometry, the ions can even be partially neutralized before hitting the wafer surface, giving some additional control.

Further control to correct the imperfections caused by the non-uniform deposition pattern of standard magnetrons can by imposed by dynamically shaping the magnetic field, for example, by using electromagnetic devices.

The systems and methods ionize the neutral atoms by employing a magnetron effect at the wafer substrate. By establishing a magnetic field in the vicinity of the substrate to trap electrons, the neutral atoms traveling to the substrate can be ionized by collisions with the electron cloud. The electrons in this magnetic confinement can have sufficient energy to ionize incoming atoms and not being annihilated by the ions. A high proportion of the incoming atoms can be excited by this electron cloud and then accelerated by a back bias field onto the wafer surface. The high number of mobile ions at the surface can provide enough surface mobility to significantly decrease the required deposition temperature, possibly even down to room temperature.

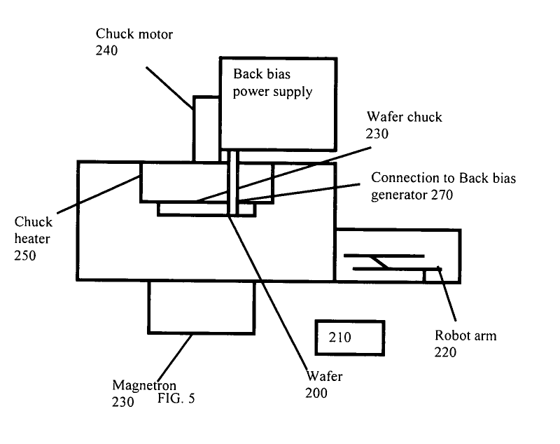

FIG. 5 shows one embodiment of an FTS system. In this embodiment, a wafer 200 is positioned in a chamber 210. The wafer 200 is moved into the chamber 210 using a robot arm 220. The robot arm 220 places the wafer 200 on a wafer chuck 230. The wafer chuck 230 is moved by a chuck motor 240. One or more chuck heaters 250 heats the wafer 200 during processing.

Additionally, the wafer 200 is positioned between the heater 250 and a magnetron 260. The magnetron 260 serves as highly efficient sources of microwave energy. In one embodiment, microwave magnetrons employ a constant magnetic field to produce a rotating electron space charge. The space charge interacts with a plurality of microwave resonant cavities to generate microwave radiation. One electrical node 270 is provided to a back-bias generator.

In the system of FIG. 5, two target plates are respectively connected and disposed onto two target holders which are fixed to both inner ends of the chamber 210 so as to make the target plates face each other. A pair of permanent magnets are accommodated in the target holders so as to create a magnetic field therebetween substantially perpendicular to the surface of the target plates. The wafer 200 is disposed closely to the magnetic field (which will define a plasma region) so as to preferably face it. The electrons emitted from the both target plates by applying the voltage are confined between the target plates because of the magnetic field to promote the ionization of the inert gas so as to form a plasma region. The positive ions of the inert gas existing in the plasma region are accelerated toward the target plates. The bombardment of the target plates by the accelerated particles of the inert gas and ions thereof causes atoms of the material forming the plates to be emitted. The wafer 200 on which the thin film is to be disposed is placed around the plasma region, so that the bombardment of these high energy particles and ions against the thin film plane is avoided because of effective confinement of the plasma region by the magnetic field. The back-bias RF power supply causes an effective DC ‘back-bias’ between the wafer 200 and the chamber 210. This bias is negative, so it repels the low-velocity electrons. By also moving the magnetron or chuck vertically with motor 260 such that the distance between them is changed during deposition, the uniformity of the magnetic field can further be increased.

It is to be understood that various terms employed in the description herein are interchangeable. Accordingly, the above description of the invention is illustrative and not limiting. Further modifications will be apparent to one of ordinary skill in the art in light of this disclosure.

The invention has been described in terms of specific examples which are illustrative only and are not to be construed as limiting. The invention may be implemented in digital electronic circuitry or in computer hardware, firmware, software, or in combinations of them.

Apparatus of the invention for controlling the fabrication equipment may be implemented in a computer program product tangibly embodied in a machine-readable storage device for execution by a computer processor; and method steps of the invention may be performed by a computer processor executing a program to perform functions of the invention by operating on input data and generating output. Suitable, processors include, by way of example, both general and special purpose microprocessors. Storage devices suitable for tangibly embodying computer program instructions include all forms of non-volatile memory including, but not limited to: semiconductor memory devices such as EPROM, EEPROM, and flash devices; magnetic disks (fixed, floppy, and removable); other magnetic media such as tape; optical media such as CD-ROM disks; and magneto-optic devices. Any of the foregoing may be supplemented by, or incorporated in, specially-designed application-specific integrated circuits (ASICs) or suitably programmed field programmable gate arrays (FPGAs).

While the preferred forms of the invention have been shown in the drawings and described herein, the invention should not be construed as limited to the specific forms shown and described since variations of the preferred forms will be apparent to those skilled in the art. Thus the scope of the invention is defined by the following claims and their equivalents.

What is claimed is:

1. A wafer magnetron, comprising:
a support for supporting a wafer;
a generator to provide an electric field substantially perpendicular to the wafer surface; and
a magnet system for generating a magnetic field, a portion of the magnetic field lines being parallel to the wafer surface.

2. The wafer magnetron of claim 1, comprising a by a back bias system electrically coupled to the wafer to generate the electric field.

3. The wafer magnetron of claim 1, wherein the electric field is generated by a power supply that generates a plasma.

4. The wafer magnetron of claim 1, further comprising a motor drive to move the magnet system.

5. The wafer magnetron of claim 1, wherein the magnet system is positioned under the wafer or on the side of the wafer.

6. The wafer magnetron of claim 1, wherein the magnetic field lines radiate from the center to the outer edge of the wafer.

7. The wafer magnetron of claim 1, further comprising an electron source.

8. A wafer magnetron processing chamber comprising
a vacuum process chamber;
a plasma generator to generate a plasma within the process chamber;
a support for supporting a wafer, the wafer positioned within the process chamber;
a generator to provide an electric field substantially perpendicular to the wafer surface; and
a magnet to generate a magnetic field having a portion of the magnetic field lines parallel to the wafer surface.

9. The wafer magnetron processing chamber of claim 8, wherein the electric field is formed by the plasma generator.

10. The wafer magnetron processing chamber of claim 8, comprising a back bias power supply electrical connected to the wafer to provide the electric field.

11. The wafer magnetron processing chamber of claim 8, comprising a sputtering assembly having a target for sputter deposition.

12. The wafer magnetron processing chamber of claim 11, wherein the sputtering assembly is a planar magnetron, a hollow cathode magnetron, a s-gun sputtering assembly, or a facing target system sputtering assembly.

13. The wafer magnetron processing chamber of claim 8, comprising a heater to heat the wafer.

14. The wafer magnetron processing chamber of claim 8, comprising an electron source.

15. A method for processing a semiconductor wafer, comprising:
trapping electrons in the vicinity region of the wafer surface by a wafer magnetron effect,
wherein the trapped electrons ionize the atoms and ions before reaching the wafer surface; and
increasing an ionization rate for atoms and ions bombarding the wafer surface.

16. The method of claim 15, comprising trapping the electrons in a closed loop drift path.

17. The method of claim 15, wherein the trapped electrons are from secondary electrons emitted from the wafer due to bombardment or from an electron source.

18. The method of claim 15, comprising generating a cross magnetic field and electric field to provide the wafer magnetron effect.

19. The method of claim 18, comprising generating the magnetic field from a magnet system located near the wafer.

20. The method of claim 18, comprising generating the electric field using a back bias power supply electrically coupled to the wafer.
